(19) United States
(12) Patent Application Publication
(10) Pub. No.: US 2025/0072301 A1
(43) Pub. Date: Feb. 27, 2025

(54) METHOD FOR MANUFACTURING RESISTIVE RANDOM ACCESS MEMORY AND RESISTIVE RANDOM ACCESS MEMORY CHIP

(71) Applicant: Shanghai Huali Integrated Circuit Corporation, Shanghai (CN)

(72) Inventors: Wuzhi ZHANG, Shanghai (CN); Yamin Cao, Shanghai (CN); Bin Yang, Shanghai (CN); Wei Zhou, Shanghai (CN); Yansheng Wang, Shanghai (CN)

(73) Assignee: Shanghai Huali Integrated Circuit Corporation, Shanghai (CN)

(21) Appl. No.: 18/668,014

(22) Filed: May 17, 2024

(30) Foreign Application Priority Data
Aug. 24, 2023 (CN) 202311076229.9

(51) Int. Cl. H10N 70/00; G11C 13/00

(52) U.S. Cl. CPC H10N 70/021; G11C 13/0007; H10N 70/041; H10N 70/063; H10N 70/8833

(57) ABSTRACT

The present disclosure provides a method for manufacturing a resistive random access memory, wherein a resistive random access memory chip manufactured thereby includes a first-type resistive random access memory cell and a second-type resistive random access memory cell, a resistive layer of the first-type resistive random access memory cell includes a high voltage material layer, and a resistive layer of the second-type resistive random access memory cell is a high dielectric constant material layer. The first-type resistive random access memory cell is characterized by a long storage time, and the second-type resistive random access memory cell characterized by a fast response and a high computing speed. The method for manufacturing a resistive random access memory has an innovative process that allows process integration of two types of resistive random access memory cells, so that the manufactured random access memory chip is able to meet two types of performance demands.

### CROSS-REFERENCES TO RELATED APPLICATIONS

This application claims priority to Chinese patent application No. CN 202311076229.9, filed on Aug. 24, 2023 at CNIPA, and entitled “METHOD FOR MANUFACTURING RESISTIVE RANDOM ACCESS MEMORY AND RESISTIVE RANDOM ACCESS MEMORY CHIP”, the disclosure of which is incorporated herein by reference in entirety.

### TECHNICAL FIELD

The present disclosure relates to memory technologies, and in particular, to a method for manufacturing a resistive random access memory and a resistive random access memory chip.

### BACKGROUND

The resistive random access memory (RRAM) belongs to a class of prospective next-generation non-volatile memories based on a material with a resistance that is reversibly switchable between a high-resistance state and a low-resistance state under the action of an external electric field. It has the potential to replace the existing mainstream flash memory at the nodes of and below 32 nm, and has become an important research direction for current novel memories.

The RRAM device of a typical “sandwich” (MIM) structure has a resistive switching layer material between upper and lower plates thereof, which is capable of a resistive switch. Under the action of an external bias voltage, the resistance of the device is switched between the high-resistance state and the low-resistance state, thereby implementing the storage of “0” and “1”. Unlike a charge storage mechanism of the conventional floating gate flash, the RRAM is a non-charge storage mechanism, which can solve the problem of a charge leakage caused by thinning of a tunneling oxide layer in the flash, and therefore has better ability to reduce.

In the design of the typical RRAM structure, a resistive switching layer is provided between a top plate (TP) and a bottom plate (BP). The resistive switching layer is usually made of a high dielectric constant (High k, HK) material such as HfOx, TaOx or TiOx. The RRAM with the HK resistive switching layer is characterized by a fast response and a high computing speed and applicable to artificial intelligence, but has the disadvantage of poor durability when used as a memory.

### BRIEF SUMMARY

The present disclosure provides a method for manufacturing a resistive random access memory (RRAM), so that a manufactured random access memory (RRAM) chip includes both a first-type resistive random access memory cell characterized by a long storage time and a second-type resistive random access memory cell characterized by a fast response and a high computing speed, and therefore is able to meet two types of performance demands.

The method for manufacturing a resistive random access memory provided by the present disclosure includes the following steps:
S1. forming a lower interlayer dielectric layer 1 on a substrate, and completing a metal layer process to form a first area lower metal layer 11 and a second area lower metal layer 12 in the lower interlayer dielectric layer 1, wherein upper surfaces of the first area lower metal layer 11 and the second are lower metal layer 12 are flush with the lower interlayer dielectric layer 1;
S2. covering the lower interlayer dielectric layer 1, the first area lower metal layer 11, and the second area lower metal layer 12 with a barrier layer 2;
S3. forming contact vias in the barrier layer 2 that are respectively communicated with the first area lower metal layer 11 and the second are lower metal layer 12;
S4. depositing a bottom plate metal layer 3 on a wafer, wherein the bottom plate metal layer 3 is respectively in short-circuit with the first area lower metal layer 11 and the second area lower metal layer 12 through the contact vias;
S5. depositing a high voltage material layer 4 on the bottom plate metal layer 3;
S6. defining a high voltage area by means of a photoetch/etch process, wherein the high voltage area is located directly above the first area lower metal layer 11, removing the high voltage material layer 4 outside the high voltage area, and retaining the high voltage material layer 4 in the high voltage area;
S7. depositing a high dielectric constant material layer 5 on the wafer;
S8. defining a high dielectric constant area by means of a photoetch/etch process, wherein the high dielectric constant area is located directly above the second area lower metal layer 12, removing the high dielectric constant material layer 5 outside the high voltage area and the high dielectric constant area, and retaining the high dielectric constant material layer 5 in the high voltage area and the high dielectric constant area; alternatively, removing the high dielectric constant material layer 5 outside the high dielectric constant area, and retaining only the high dielectric constant material layer 5 in the high dielectric constant area;
S9. depositing a top plate metal layer 6 on the wafer;
S10. removing the top plate metal layer 6 outside the high voltage area and the high dielectric constant area by means of a photoetch/etch process, and retaining the top plate metal layer 6 in the high voltage area and the high dielectric constant area; and
S11. performing a subsequent process to form, on the same chip, a first-type resistive random access memory cell with a resistive layer including the high voltage material layer 4 and a second-type resistive random access memory cell with a resistive layer being the high dielectric constant material layer 5.

In some examples, step S11 includes the following steps:
S111. depositing a surface protection layer 7 on the wafer;
S112. depositing a low dielectric constant material layer 8 on the surface protection layer 7;
S113. planarizing the low dielectric constant material layer 8 by means of CMP; and
S114. forming, above the low dielectric constant material layer 8, a first area upper metal layer 91 in short-circuit with the top plate metal layer 6 in the high voltage area through the contact via, and a second area upper metal layer 92 in short-circuit with the top plate metal layer 6 in the high dielectric constant area through the contact via.

In some examples, the high voltage material layer 4 is silicon nitride or silicon oxide.

In some examples, the thickness of the high voltage material layer 4 is 500 Å-2000 Å.

In some examples, the high dielectric constant material layer 5 is hafnium oxide HfOx, tantalum oxide TaOx, titanium oxide TiOx, or zirconium oxide ZrO₂.

In some examples, the thickness of the high dielectric constant material layer 5 is 100 Å-1000 Å.

In some examples, the thickness of the high voltage material layer 4 is 900 Å-1100 Å.

In some examples, the thickness of the high dielectric constant material layer (5) is 400 Å-600 Å.

In some examples, the surface protection layer 7 is silicon nitride or silicon oxide;
the low dielectric constant layer 8 is porous silicon oxide, silicon nitride or silicon nitride oxide;
the bottom plate metal layer 3 is TiN, W, Pt, or Pd;
the top plate metal layer 6 is TiN, Ti, Al, or W;
the barrier layer 2 is nitrogen-doped silicon carbide;
the lower interlayer dielectric layer 1 is silicon dioxide, silicon nitride, silicon oxynitride, fluorosilicate glass, carbon-doped silicon oxide, or nitrogen-doped silicon oxide; and
the first area lower metal layer 11 and second area lower metal layer 12 are copper.

In order to solve the above technical problem, the present disclosure provides a resistive random access memory chip, including a first-type resistive random access memory cell and a second-type resistive random access memory, wherein
a resistive layer of the first-type resistive random access memory cell includes a high voltage material layer 4; and
a resistive layer of the second-type resistive random access memory cell is a high dielectric constant material layer 5.

In some examples, the high voltage material layer 4 is silicon nitride or silicon oxide; and
the high dielectric constant material layer 5 is hafnium oxide HfOx, tantalum oxide TaOx, titanium oxide TiOx, or zirconium oxide ZrO₂.

The resistive random access memory (RRAM) chip manufactured by the method for manufacturing a resistive random access memory (RRAM) of the present disclosure includes the first-type resistive random access memory cell and the second-type resistive random access memory cell, wherein the resistive layer of the first-type resistive random access memory cell includes the high voltage material layer 4, and the resistive layer of the second-type resistive random access memory cell is the high dielectric constant material layer (HK) 5. The first-type resistive random access memory cell is characterized by a long storage time due to the resistive layer thereof including the high voltage material layer 4, and the second-type resistive random access memory cell characterized by a fast response and a high computing speed due to the resistive layer thereof being the high dielectric constant material layer (HK) 5. The method for manufacturing a resistive random access memory (RRAM) has an innovative process flow that allows process integration of two types of resistive random access memory (RRAM) cells, so that the manufactured random access memory (RRAM) chip includes both the first-type resistive random access memory cell characterized by the long storage time and the second-type resistive random access memory cell characterized by the fast response and high computing speed, and therefore is able to meet two types of performance demands.

### BRIEF DESCRIPTION OF THE DRAWINGS

In order to more clearly explain the technical solutions of the present disclosure, the drawings required to be used in the present disclosure will be briefly described below. It is obvious that the drawings described below are merely some embodiments of the present disclosure, and those skilled in the art could also obtain other drawings on the basis of these drawings without the practice of inventive effort.

FIG. 1 to FIG. 10 are process flow diagrams of a method for manufacturing a resistive random access memory of the present disclosure.

### LIST OF REFERENCE NUMERALS

1. lower interlayer dielectric layer; 11. first area lower metal layer 11; 12. second area lower metal layer; 2. barrier layer; 3. bottom plate metal layer; 4. high voltage material layer; 5. high dielectric constant material layer; 6. top plate metal layer; 7. surface protection layer; 8. low dielectric constant material layer 8; 91. first area upper metal layer; and 92. second area upper metal layer.

### DETAILED DESCRIPTION OF THE DISCLOSURE

The technical solutions in the embodiments of the present disclosure will be clearly and completely described below in conjunction with the drawings. Obviously, the described embodiments are only part of the embodiments of the present disclosure, rather than all of the embodiments. Based on the embodiments in the present disclosure, all other embodiments obtained by those skilled in the art without the practice of inventive effort shall fall into the protection scope of the present disclosure.

The terms such as “first” and “second” used in the present disclosure do not indicate any order, quantity, or importance, but are only used to distinguish different constituent parts. The terms such as “include” or “comprise” means that the components or objects in front of these terms cover the components or objects listed after the terms and equivalents thereof, but does not exclude other components or objects. The terms such as “connection” or “coupling” are not limited to physical or mechanical connections, but may include electrical connections, whether direct or indirect. The terms such as “upper”, “lower”, “left”, “right”, “front”, and “rear” are only used to represent relative positional relationships, which may be changed accordingly after absolute positions of the described objects are changed.

It should be noted that the embodiments or features in the embodiments of the present disclosure can be combined with each other in the case of no conflicts.

### Embodiment I

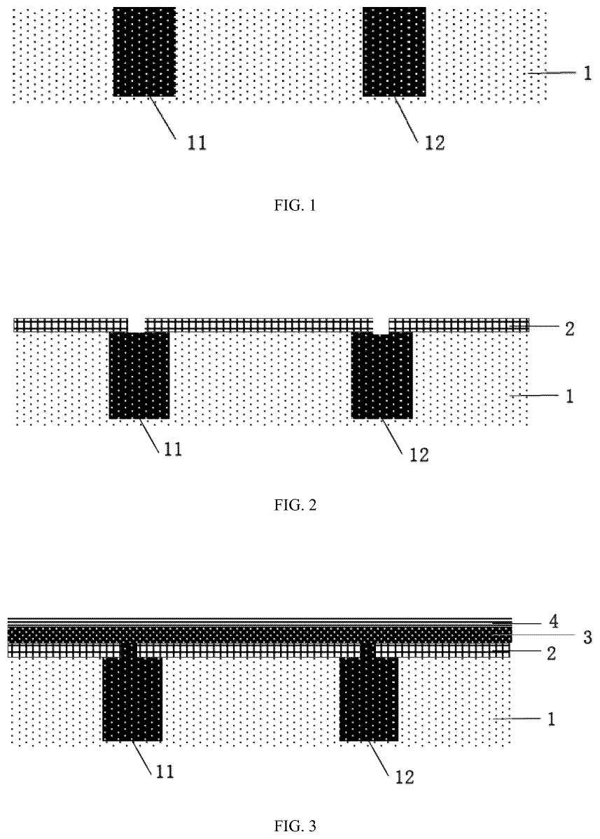

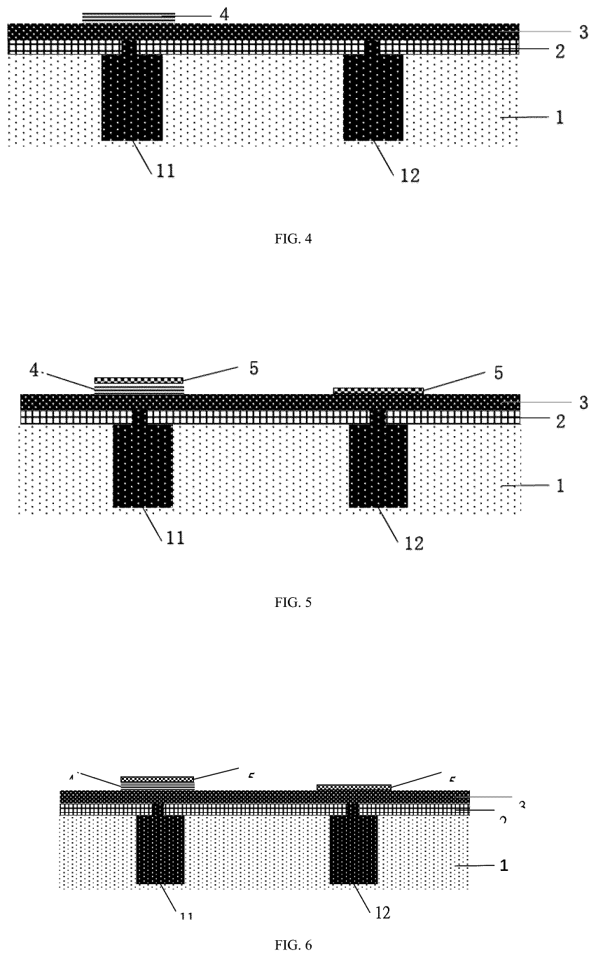

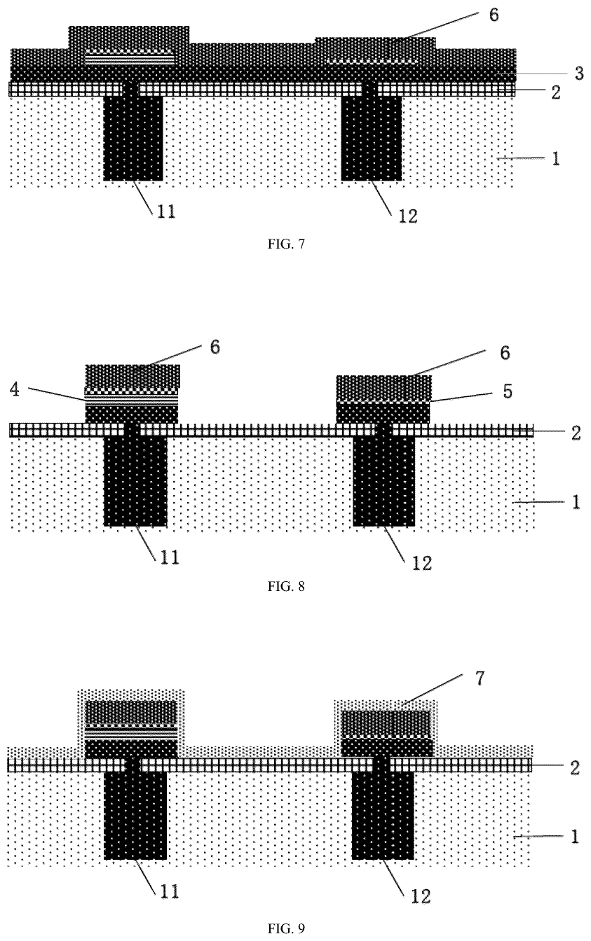

Referring to FIG. 1 to FIG. 7, a method for manufacturing a resistive random access memory (RRAM) includes the following steps:
S1. forming a lower interlayer dielectric layer 1 on a substrate, and completing a metal layer process (Mx Process) to form a first area lower metal layer 11 and a second area lower metal layer 12 in the lower interlayer dielectric layer 1, wherein upper surfaces of the first area lower metal layer 11 and the second are lower metal layer 12 are flush with the lower interlayer dielectric layer 1;
S2. covering the lower interlayer dielectric layer 1, the first area lower metal layer 11, and the second area lower metal layer 12 with a barrier layer 2;
S3. forming contact vias in the barrier layer 2 that are respectively communicated with the first area lower metal layer 11 and the second are lower metal layer 12, as shown in FIG. 2;
S4. depositing a bottom plate metal layer 3 on a wafer, wherein the bottom plate metal layer 3 is respectively in short-circuit with the first area lower metal layer 11 and the second area lower metal layer 12 through the contact vias;
S5. depositing a high voltage material layer 4 on the bottom plate metal layer 3, as shown in FIG. 3;
S6. defining a high voltage (HV) area by means of a photoetch/etch (PH/ET) process, wherein the high voltage (HV) area is located directly above the first area lower metal layer 11, removing the high voltage material layer 4 outside the high voltage (HV) area, and retaining the high voltage material layer 4 in the high voltage (HV) area, as shown in FIG. 3;
S7. depositing a high dielectric constant (High k, HK) material layer 5 on the wafer, as shown in FIG. 5;
S8. defining a high dielectric constant (HK) area by means of a photoetch/etch (PH/ET) process, wherein the high dielectric constant (HK) area is located directly above the second area lower metal layer 12, removing the high dielectric constant (High k, HK) material layer 5 outside the high voltage (HV) area and the high dielectric constant (HK) area, and retaining the high dielectric constant (High k, HK) material layer 5 in the high voltage (HV) area and the high dielectric constant (HK) area, as shown in FIG. 6; alternatively, removing the high dielectric constant (High k, HK) material layer 5 outside the high dielectric constant (HK) area, and retaining only the high dielectric constant (High k, HK) material layer 5 in the high dielectric constant (HK) area;
S9. depositing a top plate metal layer 6 on the wafer, as shown in FIG. 7;
S10. removing the top plate metal layer 6 outside the high voltage (HV) area and the high dielectric constant (HK) area by means of a photoetch/etch process (PH/ET), and retaining the top plate metal layer 6 in the high voltage (HV) area and the high dielectric constant (HK) area, as shown in FIG. 8; and
S11. performing a subsequent process to form, on the same chip, a first-type resistive random access memory cell with a resistive layer including the high voltage material layer 4 and a second-type resistive random access memory cell with a resistive layer being the high dielectric constant (HK) material layer 5.

The resistive random access memory (RRAM) chip manufactured by the method for manufacturing a resistive random access memory (RRAM) of Embodiment I includes the first-type resistive random access memory cell and the second-type resistive random access memory cell, wherein the resistive layer of the first-type resistive random access memory cell includes the high voltage material layer 4, and the resistive layer of the second-type resistive random access memory cell is the high dielectric constant material layer (HK) 5. The first-type resistive random access memory cell is characterized by a long storage time due to the resistive layer thereof including the high voltage material layer 4, and the second-type resistive random access memory cell characterized by a fast response and a high computing speed due to the resistive layer thereof being the high dielectric constant material layer (HK) 5.

The method for manufacturing a resistive random access memory (RRAM) of Embodiment I has an innovative process flow that allows process integration of two types of resistive random access memory (RRAM) cells, so that the manufactured random access memory (RRAM) chip includes both the first-type resistive random access memory cell characterized by the long storage time and the second-type resistive random access memory cell characterized by the fast response and high computing speed, and therefore is able to meet two types of performance demands.

### Embodiment II

Step 11 of the method for manufacturing a resistive random access memory (RRAM) based on Embodiment I includes the following steps:

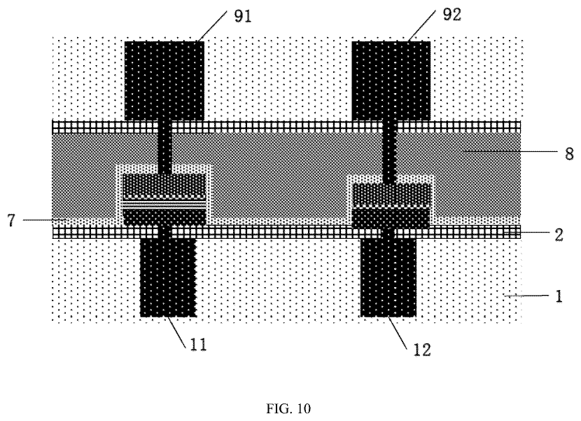

S111. depositing a surface protection layer 7 on the wafer, as shown in FIG. 9;

S112. depositing a low dielectric constant (Low K) material layer 8 on the surface protection layer 7;

S113. planarizing the low dielectric constant (Low K) material layer 8 by means of chemical mechanical polishing (CMP); and

S114. forming, above the low dielectric constant (Low K) material layer 8, a first area upper metal layer 91 in short-circuit with the top plate metal layer 6 in the high voltage (HV) area through the contact via, and a second area upper metal layer 92 in short-circuit with the top plate metal layer 6 in the high dielectric constant (HK) area through the contact via, as shown in FIG. 10.

In some examples, the high voltage material layer 4 is silicon nitride or silicon oxide.

In some examples, the thickness of the high voltage material layer 4 is 500 Å-2000 Å (for example, the thickness of the high voltage material layer 4 is 900 Å-1100 Å).

In some examples, the high dielectric constant (High k, HK) material layer 5 is hafnium oxide HfOx, tantalum oxide TaOx, titanium oxide TiOx, or zirconium oxide ZrO₂, etc.

In some examples, the thickness of the high dielectric constant (High k, HK) material layer 5 is 100 Å-1000 Å (for example, the thickness of the HK material layer 4 is 400 Å-600 Å).

In some examples, the surface protection layer 7 is silicon nitride or silicon oxide.

In some examples, the low dielectric constant (Low K) layer 8 is porous silicon oxide, silicon nitride or silicon nitride oxide, etc.

In some examples, the bottom plate metal layer 3 is TiN, W, Pt, or Pd, etc.

In some examples, the top plate metal layer 6 is TiN, Ti, or Al, etc.

In some examples, the barrier layer 2 is nitrogen-doped silicon carbide (N Doped SiC, NDC)

In some examples, the lower interlayer dielectric layer 1 is silicon dioxide, silicon nitride, silicon oxynitride, fluorosilicate glass (FSG), carbon-doped silicon oxide, or nitrogen-doped silicon oxide, etc.

In some examples, the first area lower metal layer 11 and second area lower metal layer 12 are copper.

The above descriptions are merely examples of the embodiments of the present disclosure and are not intended to limit the present disclosure. Any modifications, equivalent substitutions, improvements, etc. made within the spirit and principles of the present disclosure shall be included within the protection scope of the present disclosure.

What is claimed is:

1. A method for manufacturing a resistive random access memory, comprising the following steps:
S1. forming a lower interlayer dielectric layer (1) on a substrate, and completing a metal layer process to form a first area lower metal layer (11) and a second area lower metal layer (12) in the lower interlayer dielectric layer (1), wherein upper surfaces of the first area lower metal layer (11) and the second are lower metal layer (12) are flush with the lower interlayer dielectric layer (1);
S2. covering the lower interlayer dielectric layer (1), the first area lower metal layer (11), and the second area lower metal layer (12) with a barrier layer (2);
S3. forming contact vias in the barrier layer (2) that are respectively communicated with the first area lower metal layer (11) and the second are lower metal layer (12);
S4. depositing a bottom plate metal layer (3) on a wafer, wherein the bottom plate metal layer (3) is respectively in short-circuit with the first area lower metal layer (11) and the second area lower metal layer (12) through the contact vias;
S5. depositing a high voltage material layer (4) on the bottom plate metal layer (3);
S6. defining a high voltage area by means of a photoetch/etch process, wherein the high voltage area is located directly above the first area lower metal layer (11), removing the high voltage material layer (4) outside the high voltage area, and retaining the high voltage material layer (4) in the high voltage area;
S7. depositing a high dielectric constant material layer (5) on the wafer;
S8. defining a high dielectric constant area by means of a photoetch/etch process, wherein the high dielectric constant area is located directly above the second area lower metal layer (12), removing the high dielectric constant material layer (5) outside the high voltage area and the high dielectric constant area, and retaining the high dielectric constant material layer (5) in the high voltage area and the high dielectric constant area; alternatively, removing the high dielectric constant material layer (5) outside the high dielectric constant area, and retaining only the high dielectric constant material layer (5) in the high dielectric constant area;
S9. depositing a top plate metal layer (6) on the wafer;
S10. removing the top plate metal layer (6) outside the high voltage area and the high dielectric constant area by means of a photoetch/etch process, and retaining the top plate metal layer (6) in the high voltage area and the high dielectric constant area; and
S11. performing a subsequent process to form, on the same chip, a first-type resistive random access memory cell with a resistive layer comprising the high voltage material layer (4) and a second-type resistive random access memory cell with a resistive layer being the high dielectric constant material layer (5).

2. The method for manufacturing a resistive random access memory according to claim 1, wherein
step S11 comprises the following steps:
S111. depositing a surface protection layer (7) on the wafer;
S112. depositing a low dielectric constant material layer (8) on the surface protection layer (7);
S113. planarizing the low dielectric constant material layer (8) by means of CMP; and
S114. forming, above the low dielectric constant material layer (8), a first area upper metal layer (91) in short-circuit with the top plate metal layer (6) in the high voltage area through the contact via, and a second area upper metal layer (92) in short-circuit with the top plate metal layer (6) in the high dielectric constant area through the contact via.

3. The method for manufacturing a resistive random access memory according to claim 1, wherein
the high voltage material layer (4) is silicon nitride or silicon oxide.

4. The method for manufacturing a resistive random access memory according to claim 1, wherein
the thickness of the high voltage material layer (4) is 500 Å-2000 Å.

5. The method for manufacturing a resistive random access memory according to claim 1, wherein
the high dielectric constant material layer (5) is hafnium oxide HfOx, tantalum oxide TaOx, titanium oxide TiOx, or zirconium oxide ZrO₂.

6. The method for manufacturing a resistive random access memory according to claim 1, wherein
the thickness of the high dielectric constant material layer (5) is 100 Å-1000 Å.

7. The method for manufacturing a resistive random access memory according to claim 1, wherein
the thickness of the high voltage material layer (4) is 900 Å-2000 Å; and
the thickness of the high dielectric constant material layer (5) is 400 Å-600 Å.

8. The method for manufacturing a resistive random access memory according to claim 2, wherein
the surface protection layer (7) is silicon nitride or silicon oxide;
the low dielectric constant layer (8) is porous silicon oxide, silicon nitride or silicon nitride oxide;
the bottom plate metal layer (3) is TiN, W, Pt, or Pd;
the top plate metal layer (6) is TiN, Ti, Al, or W;
the barrier layer (2) is nitrogen-doped silicon carbide;
the lower interlayer dielectric layer (1) is silicon dioxide, silicon nitride, silicon oxynitride, fluorosilicate glass, carbon-doped silicon oxide, or nitrogen-doped silicon oxide; and
the first area lower metal layer (11) and second area lower metal layer (12) are copper.

9. A resistive random access memory chip, comprising a first-type resistive random access memory cell and a second-type resistive random access memory, wherein
a resistive layer of the first-type resistive random access memory cell comprises a high voltage material layer (4); and
a resistive layer of the second-type resistive random access memory cell is a high dielectric constant material layer (5).

10. The resistive random access memory chip according to claim 9, wherein
the high voltage material layer (4) is silicon nitride or silicon oxide; and
the high dielectric constant material layer (5) is hafnium oxide HfOx, tantalum oxide TaOx, titanium oxide TiOx, or zirconium oxide ZrO₂.
